(19) United States
(12) Patent Application Publication
(10) Pub. No.: US 2011/0048777 A1
(43) Pub. Date: Mar. 3, 2011

(54) Component-Embedded Printed Circuit Board

(76) Inventors: Chien-Wei Chang, Taoyuan (TW); Ting-Hao Lin, Taipei (TW); Yu-Te Lu, Taoyuan (TW)

(21) Appl. No.: 12/547,456

(22) Filed: Aug. 25, 2009

(51) Int. Cl. H05K 1/16

(52) U.S. Cl. 174/260

(57) ABSTRACT

A component-embedded printed circuit board includes: a carrier plate having a metalized layer disposed thereon, an electronic component disposed on the metalized layer of the carrier plate, and a metal layer laminated onto the metalized layer having the electronic component disposed thereon by a dielectric film. The carrier plate is then removed to expose the metalized layer. At least one of the metal layer and the metalized layer is patterned to be a circuit layer.

### BACKGROUND OF THE INVENTION

1. Field of the Invention

The present invention relates generally to a circuit board, and more particularly to a printed circuit board having an embedded component.

2. The Prior Arts

Embedded passives are passive components disposed between layers of a multi-layer circuit board. The electronic components, such as capacitors or resistors are directly formed on an inner layer of the circuit board by etching or printing. Then, at least one outer layer of the circuit board is laminated onto the inner circuit board to bury the electronic component inside the multi-layer circuit board. The embedded passives are adapted to replace those discrete passives soldered to the circuit board, so as to free up space on the circuit board to pack more circuitry and active components.

Buried resistor technologies are first proposed by Ohmega Technologies, Inc., a manufacturer of OHMEGA-PLY® resistor-conductor material. The buried resistor is a thin film of a phosphorus-nickel alloy serving as a resistive element plated onto a matt side of a copper foil of an inner layer. Then, they are compressed to configure a thin core, and later processed by photo-resist processing twice and etching processing thrice, so as to configure a desired thin film resistor at a certain position. Such a thin film resistor is disposed between the layers, and thus called buried resistor.

In 1992, Zycon, a U.S. PCB manufacturer, proposed to further provide an extremely thin dielectric inner layer, e.g., 2 to 4 mils, in a high level multilayer circuit board in addition to original Vcc/GND inner layers. An integral capacitor is configured by the parallel copper layers of the circuit board, which provide a large area of the copper layer. Because the capacitor is disposed between the layers, it is named as buried capacitor (BC). The buried capacitor has advantages of avoiding noise, providing charging power, and stabilizing voltage, during operating at a basic frequency. With respect to the BC, Zycon owns several U.S. patents, i.e., U.S. Pat. No. 5,079,069, U.S. Pat. No. 5,161,086, and U.S. Pat. No. 5,155,655.

Recently, the concept of the embedded passives is applied to fabricate active components in the circuit board for increasing a packaging density. Accordingly, a recess is formed in an insulating layer, and an electronic component is embedded in the recess. However, the circuit board still has the insulating layer remained beneath the electronic component. Therefore, the overall thickness of the circuit board and density of the circuitry can be further improved.

### SUMMARY OF THE INVENTION

A primary objective of the present invention is to provide a component-embedded printed circuit board, which includes a detachable carrier plate having a metalized layer disposed thereon and disposes a component on the metalized layer. The detachable carrier plate replaces an inseparable insulating layer of a conventional component-embedded PCB, thereby reducing the thickness of the PCB and increasing the density of circuitry.

In order to achieve the objective, a component-embedded PCB according to the present invention includes a carrier plate having a metalized layer, i.e. a plating metal layer, plated thereon, an electronic component disposed on the metalized layer of the carrier plate, and a metal layer laminated onto the metalized layer and the carrier plate by a dielectric film. The carrier plate is then removed to expose the metalized layer and at least one of the metal layer and the exposed metalized layer is patterned to form a circuit layer.

### BRIEF DESCRIPTION OF THE DRAWINGS

The present invention will be apparent to those skilled in the art by reading the following detailed description of preferred embodiments thereof, with reference to the attached drawings, in which:

FIG. 1A is a schematic drawing illustrating a carrier plate and a metalized layer of a component-embedded printed circuit board according to a first embodiment of the present invention;

FIG. 1B is a schematic drawing illustrating surface mount technology (SMT) fiducial marks being provided on the metalized layer of FIG. 1A;

FIG. 1C is a schematic drawing illustrating an electronic component being disposed on the metalized layer of FIG. 1B;

FIGS. 1D-1E are schematic drawings illustrating the carrier plate, the metalized layer and the electronic component of FIG. 1C and a metal layer having a dielectric film;

FIG. 1F is a schematic drawing illustrating an opening corresponding to the electronic component being formed;

FIG. 1G is a schematic drawing illustrating the carrier plate of FIG. 1F being removed;

FIG. 1H is a schematic drawing illustrating the metal layer and the metalized layer of FIG. 1G being patterned to form circuit layers;

FIG. 2A is a partial exploded view illustrating a component-embedded PCB according to a second embodiment of the present invention before the carrier plate is removed; and

FIG. 2B is a partial exploded view illustrating a component-embedded PCB according to a third embodiment of the present invention before the carrier plate is removed.

### DETAILED DESCRIPTION OF THE PREFERRED EMBODIMENT

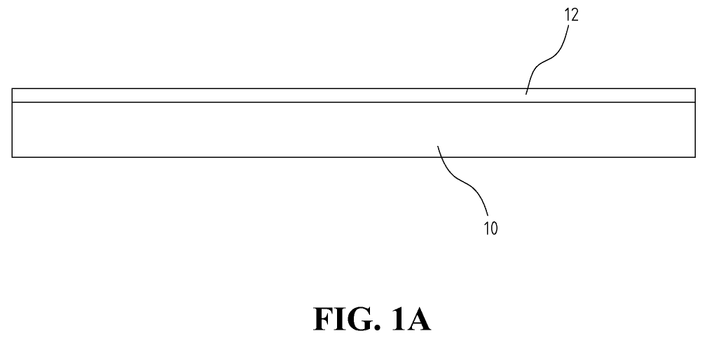

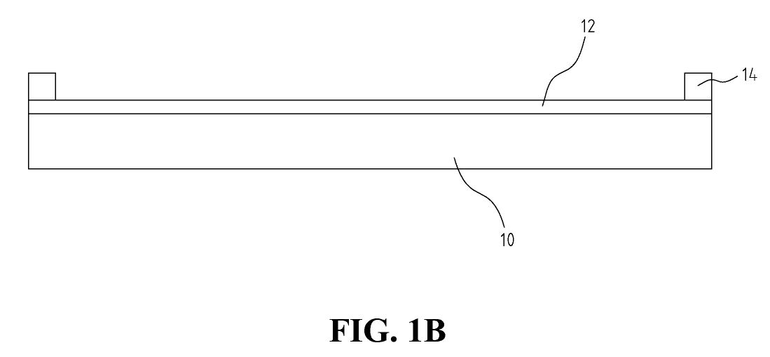

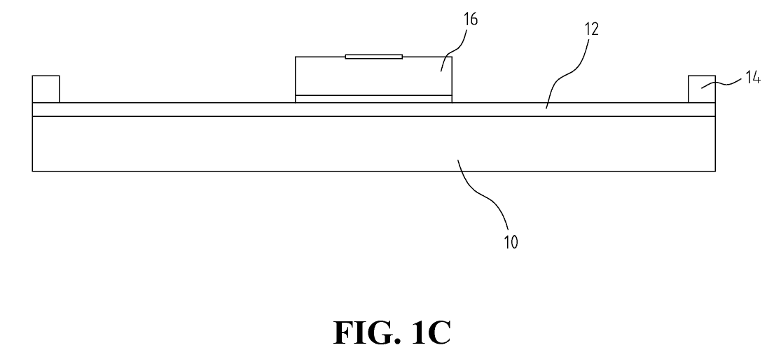

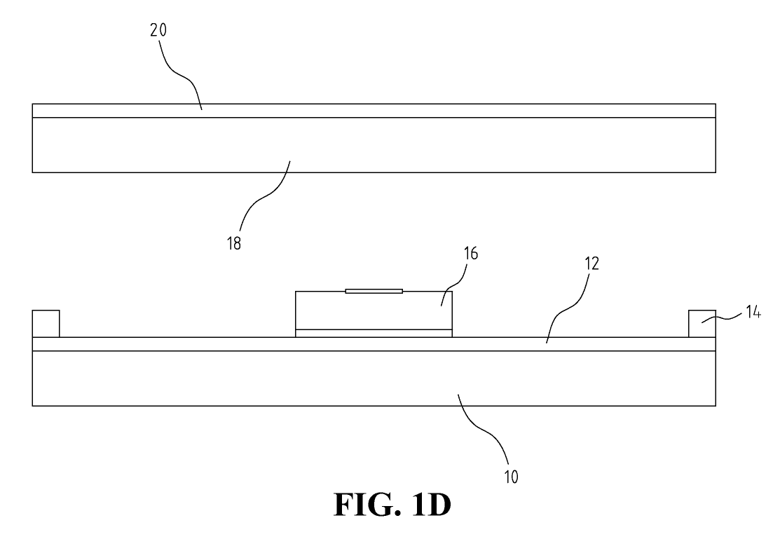

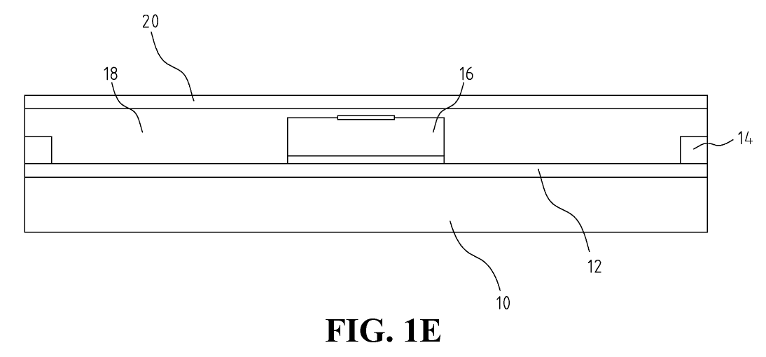

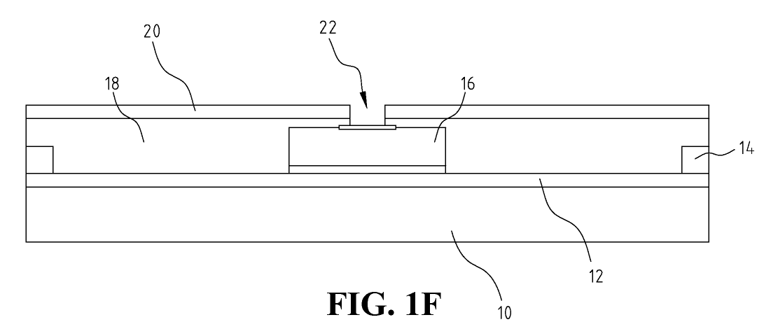

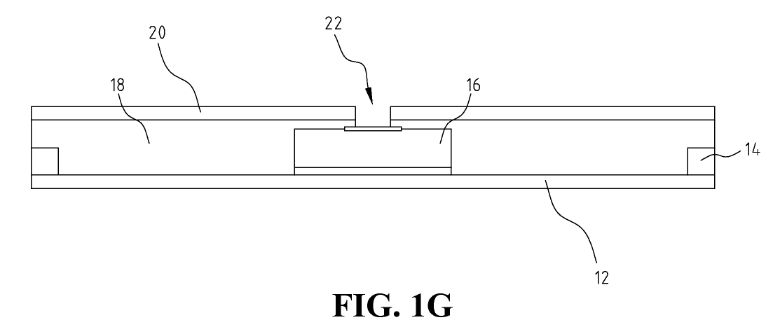

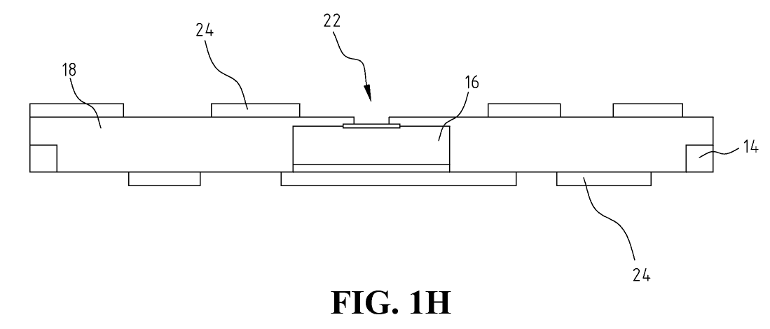

FIGS. 1A to 1H are schematic diagrams illustrating steps of fabricating a component-embedded PCB according to a first embodiment of the present invention. Referring to FIG. 1A, a metalized layer 12, e.g. a plating metal layer, is disposed on a carrier plate 10. The carrier plate 10 is made of a conductive material or an insulating material, and the metalized layer 12 is made of copper.

As shown in FIG. 1B, a plurality of surface mount technology (SMT) fiducial marks 14 are provided on the metalized layer 12 for positioning purpose. Referring to FIG. 1C, an electronic component 16 is disposed on the metalized layer 12 of the carrier plate 10. Referring to FIGS. 1D-1E, a metal layer 20 is laminated onto the metalized layer 12 having the electronic component 16 disposed thereon by a dielectric film 18. As shown in FIG. 1F, an opening 22 corresponding to the electronic component 16 is formed for the convenience of later processing a through hole (not shown) for the electronic component 16 to output signals. The carrier plate 10 is then removed from the laminated metal layer 20, the dielectric film 18, the metalized layer 12 and the carrier plate 10 to expose the metalized layer 12 as shown in FIG. 1G. Then, at least one of the metal layer 20 and the exposed metalized layer 12 is patterned to form a circuit layer 24 as shown in FIG. 1H. Therefore, the component-embedded PCB has the circuit layer 24 but does not have any insulating layer remained beneath the electronic component 16, thereby reducing a thickness of the component-embedded PCB. The component-embedded PCB according to the present invention has a higher density of circuitry than a conventional component-embedded PCB does.

The electronic component 16 may be an active component or a passive component, such as a capacitor, a resistor, or an inductance. In order to enhance the bonding between the carrier plate 10 and the metalized layer 12, the carrier plate 10 is configured with a rough surface.

In addition to the steps as shown in FIGS. 1D-1E, there are another ways to laminate the metal layer 20 onto the metalized layer 12 having the electronic component 16 disposed thereon.

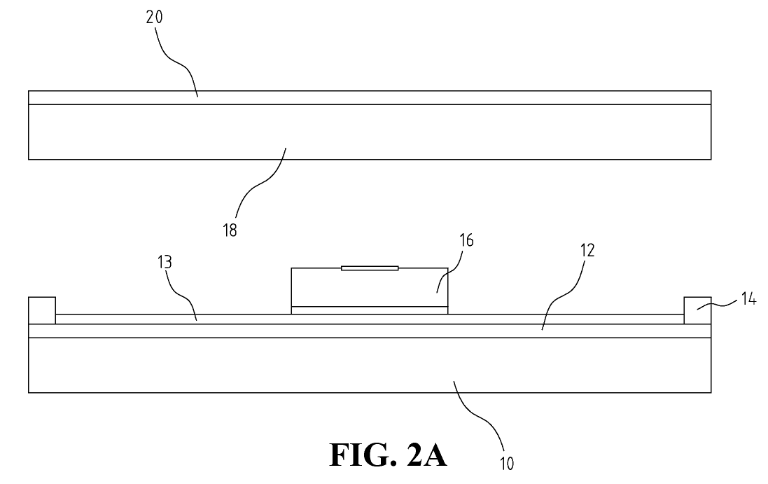

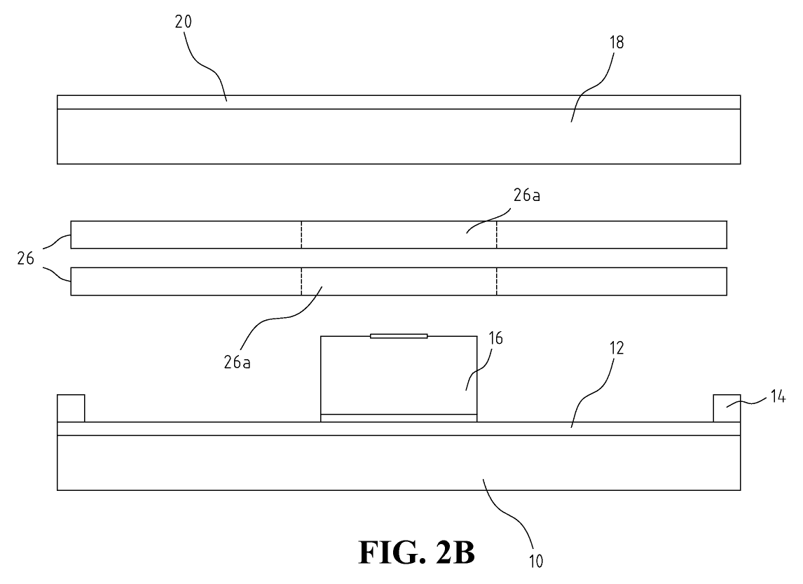

Referring to FIG. 2A, a component-embedded PCB according to a second embodiment of the present invention further includes a dielectric layer 13 disposed on the metalized layer 12 to enhance the electrical insulation. The electronic component 16 is disposed on the dielectric layer 13. Then, the metal layer 20 is laminated onto the dielectric layer 13 by the dielectric film 18 similar to FIGS. 1D-1E.

If the electronic component 16 is too thick, the electronic component 16 is likely to be damaged during the metal layer 20 being laminated onto the carrier plate 10 and the metalized layer 12 by the dielectric film 18. Referring to FIG. 2B, a component-embedded PCB according to a third embodiment of the present invention further includes two dielectric sheets 26 to prevent the electronic component 16 from damage. Each of the dielectric sheets 26 includes a cavity 26a corresponding to the electronic component 16. The dielectric sheets 26 are disposed on the metalized layer 12 and the electronic component 16 is located in the cavities of the dielectric sheets 26. Then, the carrier plate 10 and the metalized layer 12 having the electronic component 16 disposed thereon, the dielectric sheets 26, and the metal layer 20 having the dielectric film 18 are laminated together similar to FIGS. 1D-1E.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A component-embedded printed circuit board, comprising:
a carrier plate having a metalized layer disposed thereon;
an electronic component disposed on the metalized layer; and
a metal layer laminated onto the metalized layer having the electronic component disposed thereon by a dielectric film;
wherein the carrier plate is then removed to expose the metalized layer; and at least one of the metal layer and the metalized layer is patterned to be a circuit layer.

2. The component-embedded printed circuit board according to claim 1, wherein the electronic component is one of an active component and a passive component.

3. The component-embedded printed circuit board according to claim 2, wherein the passive component is one of a capacitor, a resistor, and an inductance.

4. The component-embedded printed circuit board according to claim 1, wherein the carrier plate is made of a conductive material.

5. The component-embedded printed circuit board according to claim 1, wherein the carrier plate is configured with a rough surface for enhancing bonding between the metalized layer and the carrier plate.

6. The component-embedded printed circuit board according to claim 1, further comprising a dielectric layer between the metalized layer and the electronic component.

7. The component-embedded printed circuit board according to claim 1, further comprising at least one dielectric sheet having a cavity corresponding to the electronic component; wherein the dielectric sheet is disposed between the metalized layer and the dielectric film, and the dielectric sheet is disposed around the electronic component.

8. The component-embedded printed circuit board according to claim 6, further comprising at least one dielectric sheet having a cavity corresponding to the electronic component, wherein the dielectric sheet is disposed between the dielectric layer and the dielectric film, and the dielectric sheet is disposed around the electronic component.
